(19) United States
(12) Patent Application Publication
(10) Pub. No.: US 2012/0042941 A1
(43) Pub. Date: Feb. 23, 2012

(54) Back-Side Contact Solar Cell

(75) Inventors: Robert Seguin, Berlin (DE); Sven Wanka, Leipzig (DE)

(73) Assignee: Q-CELLS SE, Bitterfeld-Wolfen, OT Thalheim (DE)

(21) Appl. No.: 13/148,970

(22) PCT Filed: Jan. 27, 2010
(86) PCT No.: PCT/DE2010/075010

§ 371 Date: Nov. 10, 2011

(30) Foreign Application Priority Data
Feb. 11, 2009 (DE) 10 2009 003 467.6

(51) Int. Cl. H01L 31/0216; H01L 31/04

(52) U.S. Cl. 136/256; 136/252

(57) ABSTRACT

A back-side contact solar cell has a semiconductor layer (1) having a semiconductor surface (15) and a semiconductor area (3) adjoining the semiconductor surface (15) in the semiconductor layer (1) An electrode (23) is electrically connected to the semiconductor area (3), wherein the semiconductor area (3) forms a contact area (31) with the electrode (23) along the semiconductor surface (15) A passivation layer (7) is disposed on the semiconductor surface (15) for passivating the semiconductor surface by means of field effect passivation, wherein the passivation layer (7) extends substantially over the entire semiconductor surface (15), and a polarized or neutral buffer layer (9) is disposed between the semiconductor layer (1) and the passivation layer and encompasses the contact area (31).

### TECHNICAL FIELD

The invention relates to a back side contact solar cell.

### BACKGROUND

In solar cells of this type both the emitter contacts and also the base contacts are applied to the back side of a solar cell. Underneath these contacts the related semiconductor regions, that is to say, the emitter and base regions, extend as far as the semiconductor surface of the back side of the solar cell. Thus the semiconductor surface of the solar cell back side has semiconductor regions with differing levels or types of doping.

To reduce recombination losses, and thereby to increase the efficiency of the solar cell, a surface-passivating passivation layer is generally applied onto the semiconductor surfaces of the solar cell, in particular onto the boundary surfaces of the contacts. Here this can take the form of a layer with a high surface charge density, which displaces minority charge carriers of a semiconductor region from the semiconductor surface so as to reduce opportunities for recombination. Passivation of this type, based on field effects, is denoted in what follows as field effect passivation.

In back side contact solar cells with the different semiconductor regions on the same semiconductor surface the problem arises that, as a rule, the passivation layer used for this purpose acts in a surface-passivating manner for just one of the semiconductor regions, while the recombination losses of other semiconductor regions, depending upon their type of doping, are hardly reduced at all, or even increase. For example, in the above described case, in which the minority charge carriers in the one semiconductor region are displaced from the semiconductor surface, in the other semiconductor region additional minority charge carriers would be attracted onto the semiconductor surface in an unfavourable manner and the opportunities for recombination would increase.

In the latter case it is indeed possible for the surface charge density to be selected to be so high that in the other semiconductor region a charge carrier inversion occurs, so that no majority charge carriers are any longer available on the semiconductor surface for purposes of recombination. However, in a transition region between the semiconductor regions this leads to short-circuit effects along the semiconductor surface; these effects are denoted as “parasitic shunting”. As a result the efficiency of the solar cell is significantly reduced.

### SUMMARY OF THE INVENTION

A resolution of this problem consists in applying the passivation layer along the semiconductor surface of a structured manner such that it covers only one of the semiconductor regions. In this regard, however, additional structuring steps, and in particular additional alignment steps during the application of the contacts, are necessary, as a result of which the manufacturing process becomes complex and expensive.

Thus it is the object of the invention to provide a back side contact solar cell in which the efficiency is improved with a relatively small level of complexity.

The object is achieved in accordance with the invention by means of a back side contact solar cell comprising a semiconductor layer with a semiconductor surface and a semiconductor region adjacent to the semiconductor surface in the semiconductor layer. An electrode is electrically connected with the semiconductor layer wherein the semiconductor region with the electrode forms a contact region along the semiconductor surface. A passivation layer is arranged on the semiconductor surface, for passivating the semiconductor surface by means of a field effect passivation. The passivation layer extends essentially over the whole semiconductor surface. Between the semiconductor layer and the passivation layer, and with regard to the field effect passivation, an oppositely polarised or neutral buffer layer is arranged, which surrounds the contact region. Advantageous further developments of the invention are presented in the dependent claims.

The invention is based on the knowledge that the short-circuit effect of parasitic shunting elucidated in the introduction to the description can be reduced or even avoided if the passivation layer arranged on the semiconductor surface, and extending essentially over the whole of the semiconductor surface, is distanced from the semiconductor surface in the vicinity of the contact region. Here the means of distancing takes the form of a buffer layer arranged between the passivation layer and the semiconductor surface.

In the manufacture of the back side contact solar cell the buffer layer can therefore be applied to some regions of the semiconductor surface, so that the passivation layer can subsequently be applied over essentially the whole surface. In further steps the through holes are then formed in the passivation layer and/or in the buffer layer as required, and subsequently an electrode layer is applied, which is structured so as to form the emitter and base contacts of the solar cell. Advantageously the passivation layer itself is not structured to any further extent, apart from the formation of the through holes as necessary.

Here the surrounding of the contact region by the buffer layer signifies a planar surround along the semiconductor surface. In other words, there is a region surrounding the contact region that is generated by the buffer layer. This arrangement fulfils the objective that in an area surrounding the contact region the passivation layer does not make contact with the semiconductor surface. This prevents an inversion layer, possibly extending as a result of the passivation layer into the semiconductor region, from reaching the contact region and causing a short-circuit. Although this is indicated in the following description and in the drawings, the buffer layer does not necessarily need to extend as far as the contact region. Rather the passivation layer can make contact with the semiconductor surface in the immediate area surrounding the contact region.

The semiconductor region forming a contact region with the electrode can be formed from a material other than that of the semiconductor layer itself. However, the semiconductor surface preferably forms a common surface for the semiconductor layer and the semiconductor region formed herein. The same is true also for any other semiconductor regions that are present.

The electrical connection between the semiconductor region and the electrode, for example, between a base region and a related base electrode, can comprise a tunnel contact, wherein the passivation layer and/or the buffer layer can serve as tunnel layers. However, in this case also the passivation layer extends over a significant proportion of the whole semiconductor surface. This signifies that the passivation layer extends at least over parts of the whole semiconductor surface that are essential for the functionality of the solar cell. This does not signify that no subdivision of the solar cell into different functional regions is possible, which would also lead to a subdivision of the passivation layer. Furthermore, electrical connection can take place by means of one or a plurality of through holes through the passivation layer and through the buffer layer as necessary, wherein a contact layer is formed in the contact region between the semiconductor region and the electrode.

Here it is not necessary for the buffer layer itself to have a surface-passivating action. This can, however, be additionally provided. For example, the buffer layer can be formed from silicon dioxide (SiO₂), which causes a surface passivation, which in part is based on field effect passivation. Furthermore, the buffer layer can comprise SiNₓ, or can be formed from a series of other suitable materials.

In a preferred form of embodiment provision is made that the passivation layer has a negative surface charge density. The passivation layer can, for example, comprise aluminium oxide (Al₂O₃). A negative surface charge density of this type is of particular advantage for the surface passivation of p-doped semiconductor regions. It is, however, also possible to use passivation layers of this type for the passivation of undoped or n-doped semiconductor regions, if the surface charge density is sufficiently high and causes an inversion layer or an inversion band on the semiconductor surface.

In an advantageous further development provision is made that the passivation layer essentially makes contact with all the semiconductor regions of the semiconductor surface not covered by the buffer layer. In other words, apart from the semiconductor regions covered by the buffer layer, no other layer is arranged between the passivation layer and the semiconductor surface.

In accordance with an advantageous embodiment provision is made that the passivation layer makes partial contact with the semiconductor region. Provision is preferably made that a ratio between the semiconductor surface covered by the buffer layer and the semiconductor surface bounding the semiconductor region lies in a range between 5 and 50%, preferably between 10 and 30%. In other words, an appropriate proportion of the semiconductor region along the semiconductor surface is covered with the buffer layer, while the remainder is covered with the passivation layer.

The buffer layer preferably surrounds the contact region up to a distance from an edge of the contact region, which lies in a range of distances from approximately 0.5 to 50 μm, preferably from approximately 10 to 30 μm. However, smaller distances can advantageously also be provided insofar as they are technically possible.

In an advantageous form of embodiment provision is made that the buffer layer covers essentially the whole semiconductor region of the semiconductor layer. In other words, a ratio between the semiconductor surface covered by the buffer layer and the semiconductor surface bounding the semiconductor region amounts to approximately 100%. The buffer layer can hereby make direct contact with the semiconductor surface layer.

In an advantageous embodiment provision is made that the semiconductor region is an emitter region, a base region, or a back side field region (BSF region.

In accordance with a preferred further development provision is made that the passivation layer is electrically insulating. Advantageously the passivation layer is moreover formed to be free of pinholes. This enables the contact electrodes, or contacts, which form the electrode layer to be dimensioned independently of the semiconductor regions. The emitter and base contacts can, for example, be symmetrically designed, that is to say, they can have essentially the same dimensions, while the emitter and base regions that are electrically connected with them are asymmetrical in design, in that, for example, the base regions in the solar cell are designed to be much smaller than the emitter regions, or at least require a smaller proportion of the semiconductor surface.

Advantageously provision is made that the passivation layer comprises aluminium oxide. In particular it is of advantage to use Al₂O₃-layers manufactured by means of atomic layer deposition (ALD) as a passivation layer. By this means, for example, the thickness of the passivation layer can be very well controlled.

In accordance with a preferred embodiment provision is made that a cover layer is formed between the passivation layer and the electrode. A cover layer of this type can serve the purpose of improving or optimising the back reflection of light penetrating through the solar cell. This cover layer can, for example, comprise SiO₂, SiNₓ and/or other suitable materials.

### BRIEF DESCRIPTION OF THE DRAWINGS

In what follows the invention is elucidated with the aid of examples of embodiment with reference to the figures. Here:

FIG. 1 shows a schematic cross-sectional view of a back side contact solar cell with asymmetric emitter and contract electrodes;

FIG. 2 shows an enlargement of the region outlined in FIG. 1; and

FIG. 3 shows a schematic cross-sectional view of a further back side contact solar cell, wherein the emitter and contract electrodes are symmetrically designed with regard to their width.

### DETAILED DESCRIPTION OF THE INVENTION

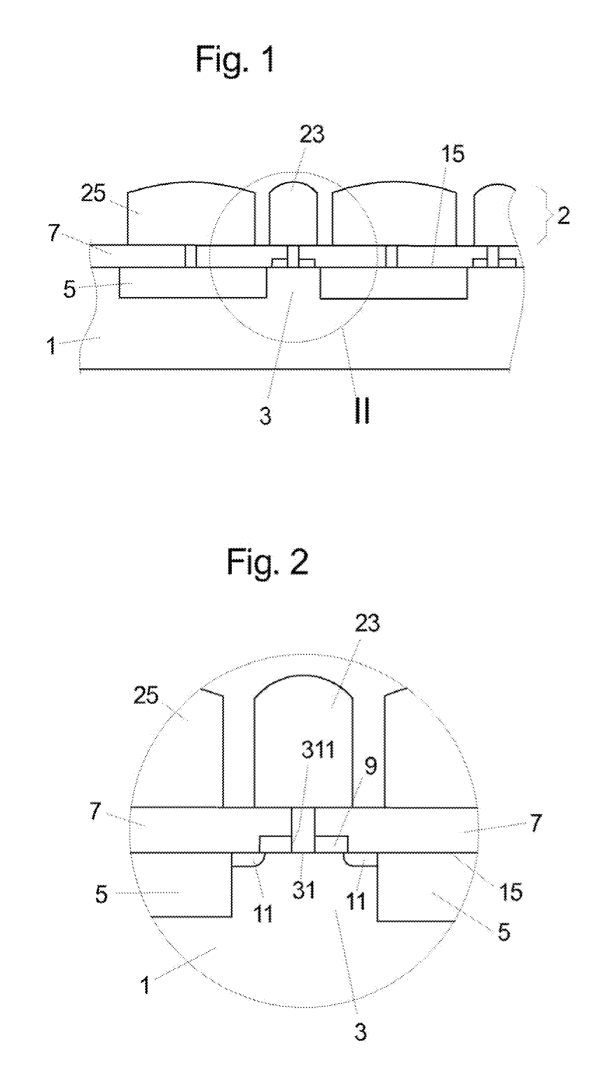

FIG. 1 shows a schematic cross-sectional view of a back side contact solar cell with a semiconductor layer 1, in which are formed a semiconductor region 3 and another semiconductor region 5. The semiconductor region 3 has the same semiconductor material and the same form of doping as the semiconductor layer 1, so that no boundary surface is formed between these. In contrast the other semiconductor region 5 has another form of doping such that during operation of the solar cell, free charge carriers generated by means of light irradiation are isolated in the boundary surface between the semiconductor region 3 and the further semiconductor region 5.

On a semiconductor surface 15 of the semiconductor layer 1 is located an electrode layer 2, which is subdivided into first contacts 23 and second contacts 25, which are electrically connected with the semiconductor region 3 and the other semiconductor region 5 respectively. For purposes of surface passivation a passivation layer 7 is arranged between the electrode layer 2 and the semiconductor layer 1.

A region II of the solar cell outlined in FIG. 1 is represented in FIG. 2 on an enlarged scale. Here it can be discerned that a buffer layer 9 is formed above the semiconductor region 3 between the semiconductor surface 15 and the passivation layer 7. In the regions where the passivation layer 7 lies directly on the semiconductor surface 15, an inversion band 11 forms in the semiconductor layer 3 along the semiconductor surface 15. The presence of the buffer layer 9 prevents this inversion band 11 from extending as far as the contact region 31, and thus generating a short-circuit. Thus the inversion band 11 essentially extends only as far as the buffer layer 9, which surrounds an edge 311 of the contact region 31.

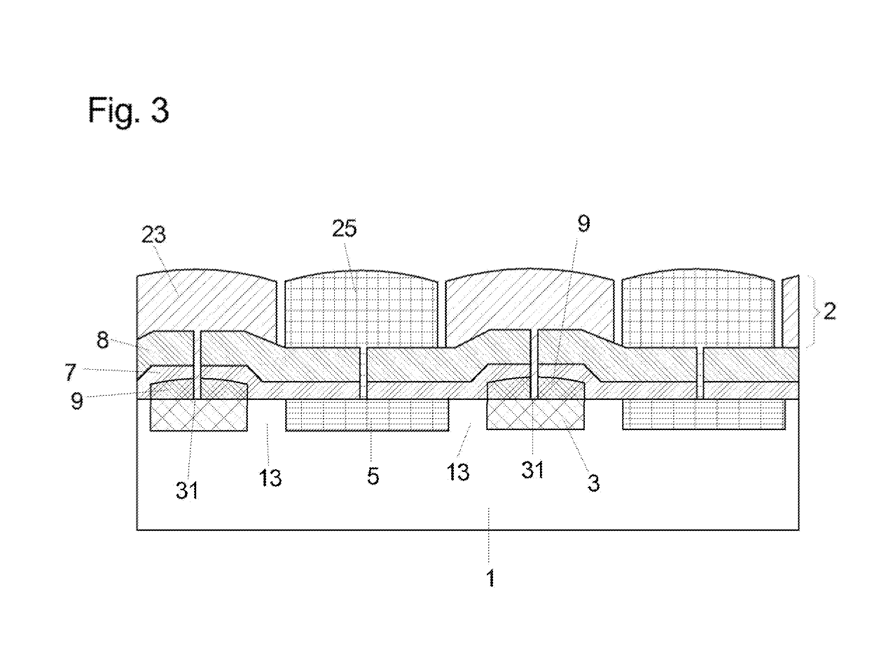

A further form of embodiment of a back side contact solar cell is represented in FIG. 3. Here the semiconductor region 3 is doped in a manner other than that for the semiconductor layer 1. For example, the semiconductor layer 1 can be an n-doped base layer, in which a semiconductor region 3, doped, for example, with phosphorus and as a result n⁺-conducting, is formed as a BSF region. In contrast, the other semiconductor layer 5 can be an emitter region, which, for example, is made p⁺-conducting by means of boron doping.

In a manner other than in FIGS. 1 and 2, the buffer layer 9 represented in FIG. 3 has essentially the same surface dimensions along the semiconductor surface 15 as the semiconductor region 3. In other words, the semiconductor region 3 is essentially fully covered by the buffer layer 9. This has the advantage that no inversion band 11 can form in the semiconductor region 3, as is the case in the arrangement represented in FIG. 2.

Furthermore, a cover layer 8 is formed between the electrode layer 2 and the passivation layer 7. The cover layer 8 can serve the purpose of improving or optimising the electrical and/or optical properties of the solar cell. For example, it can act as a reflection layer so as to reflect back a proportion of the light incident onto the solar cell that has not been absorbed during passage through the semiconductor layer 1, and by this means to increase the efficiency of the solar cell. To this end the cover layer 8 can, for example, be formed from SiO₂ or SiNₓ.

In both FIG. 1 and also in FIG. 3 it is indicated that the passivation layer 7 extends over the whole semiconductor surface 15, wherein it has through holes for purposes of making contact with the electrode layer 2. The two forms of embodiment of the solar cell represented in FIGS. 1 and 3 illustrate moreover, that the spatial dimensions of the contacts 23, 25 can to a great extent be independent of the spatial dimensions of the semiconductor regions 3, 5 that are electrically connected with them. While the first contacts 23 and the second contacts 25 have essentially the same dimensions, the semiconductor regions 3 are designed to be significantly smaller than the other semiconductor regions 5. This represents further degrees of freedom for the design of back side contact solar cells.

In the form of embodiment represented in FIG. 3 an intermediate region 13 is located along the semiconductor surface 15 between the two semiconductor regions 3 and 5; this possesses the same conduction properties as the semiconductor layer 1 itself. In an alternative form of embodiment an intermediate region 13 of this type can be dispensed with. In this case (not represented) the two semiconductor regions 3 and 5 make contact with one another; as elucidated above these regions can be highly doped.

### REFERENCE SYMBOL LIST

1 Semiconductor layer

11 Inversion band

13 Intermediate region

15 Semiconductor surface

2 Electrode layer

23 First contact

25 Second contact

3 Semiconductor region (BSF, base)

31 Contact region

311 Edge of the contact region

5 Other semiconductor region (emitter)

7 Passivation layer

8 Cover layer

9 Buffer layer

1. A back side contact solar cell, comprising:
a semiconductor layer (1) with a semiconductor surface (15) and a semiconductor region (3) adjacent to the semiconductor surface (15) in the semiconductor layer (1);
an electrode (23) electrically connected with the semiconductor layer (3), wherein the semiconductor region (3) with the electrode (23) forms a contact region (31) along the semiconductor surface (15);
a passivation layer (7), which is arranged on the semiconductor surface (15), for passivating the semiconductor surface by field effect passivation, the passivation layer (7) extending essentially over the whole semiconductor surface (15), wherein between the semiconductor layer (1) and the passivation layer (7), and with regard to the field effect passivation, an oppositely polarised or neutral buffer layer (9) is arranged, which buffer layer (9) surrounds the contact region (31).

2. The back side contact solar cell in accordance with claim 1, characterised in that the passivation layer (7) has a negative surface charge density.

3. The back side contact solar cell in accordance with claim 1 wherein the passivation layer (7) essentially makes contact with all the semiconductor regions (5, 13) of the semiconductor surface (15) not covered by the buffer layer (9).

4. The back side contact solar cell in accordance with claim 1 wherein the passivation layer (7) partially makes contact with the semiconductor region (3).

5. The back side contact solar cell in accordance with claim 4, characterised in that a ratio between the semiconductor surface (15) covered by the buffer layer (9) and the semiconductor surface (15) adjacent to the semiconductor region (3) lies in a range between 5 and 50%.

6. The back side contact solar cell in accordance with claim 1 wherein the buffer layer (9) essentially covers the whole semiconductor region (3) of the semiconductor layer (1).

7. The back side contact solar cell in accordance with claim 1 wherein the semiconductor region (3) is an emitter region, a base region, or a back side field region.

8. The back side contact solar cell in accordance with claim 1 wherein the passivation layer (7) is an electrically insulating layer electrically insulating.

9. The back side contact solar cell in accordance with claim 1 wherein the passivation layer (7) is made from aluminium oxide.

10. The back side contact solar cell in accordance with claim 1 further comprising a cover layer (8) formed between the passivation layer (7) and the electrode (23).

11. The back side contact solar cell in accordance with claim 4, characterised in that a ratio between the semiconductor surface (15) covered by the buffer layer (9) and the semiconductor surface (15) adjacent to the semiconductor region (3) lies in a range between 10 and 30%.
